(19) United States
(12) Patent Application Publication
(10) Pub. No.: US 2015/0255467 A1
(43) Pub. Date: Sep. 10, 2015

(54) SEMICONDUCTOR MEMORY DEVICE

(71) Applicant: KABUSHIKI KAISHA TOSHIBA, Tokyo (JP)

(72) Inventor: Toshikazu FUKUDA, Yokohama Kanagawa (JP)

(21) Appl. No.: 14/473,752

(22) Filed: Aug. 29, 2014

(30) Foreign Application Priority Data
Mar. 6, 2014 (JP) 2014-044232

(51) Int. Cl. H01L 27/11; H01L 29/06; H01L 29/423

(52) U.S. Cl. CPC H01L 27/1104; H01L 29/42364; H01L 29/0688

(57) ABSTRACT

According to one embodiment, a semiconductor memory device includes a retention section that retains data by using a pair of first conductivity-type load transistors and a pair of second conductivity-type drive transistors, and a transfer section with transistors that operate to transfer data to and from the retention section and has a gate length shorter than the gate length of at least one of the drive transistors and the load transistors.

### CROSS-REFERENCE TO RELATED APPLICATION

This application is based upon and claims the benefit of priority from Japanese Patent Application No. 2014-044232, filed Mar. 6, 2014, the entire contents of which are incorporated herein by reference.

### FIELD

Embodiments described herein relate generally to semiconductor memory devices.

### BACKGROUND

Static random access memory (SRAM) is used commonly in a cache memory and so forth because SRAM allows faster access than dynamic random access memory (DRAM).

A normal SRAM cell is formed of a retention section that is formed of four transistors in a cross-coupled arrangement and two transfer transistors that transfer data in and out of the retention section. While data is retained by the retention section, the transfer transistors are set in a floating state such that a leakage current does not flow through the transfer transistors. However, in actuality, there is a possibility that a leakage current flows through the transistors forming the retention section.

Therefore, all the transistors in the SRAM cell may be formed as high-voltage transistors to suppress leakage currents. The high-voltage transistor is formed by increasing a gate length, making a gate oxide film thicker, or increasing the junction depth of a diffusion layer, and has a larger circuit area than a normal transistor. Thus, if all the six transistors in the SRAM cell are formed as high-voltage transistors, the circuit area of the SRAM cell becomes considerably large, which prevents implementation of a high degree of integration.

### DESCRIPTION OF THE DRAWINGS

FIG. 1 is a layout diagram of principal portions of a semiconductor memory device according to an embodiment.

FIG. 2 is a circuit diagram of one SRAM cell.

FIG. 3A is a schematic sectional view of transfer transistors, and FIG. 3B is a schematic sectional view of drive transistors.

FIG. 4 is a layout diagram of an SRAM cell according to a comparative example.

FIG. 5A is a schematic sectional view of the transfer transistors according to a first modified example, and FIG. 5B is a schematic sectional view of the drive transistors.

FIG. 6A is a schematic sectional view of the transfer transistors according to a second modified example, and FIG. 6B is a schematic sectional view of the drive transistors.

FIG. 7A is a schematic sectional view of the transfer transistors according to a third modified example, and FIG. 7B is a schematic sectional view of the drive transistors.

### DETAILED DESCRIPTION

An embodiment provides a semiconductor memory device having reduced circuit area without degrading leakage characteristics.

In general, according to one embodiment, there is provided a semiconductor memory device including a retention section that retains data by using a first conductivity-type load transistor and a second conductivity-type drive transistor, and a transfer transistor that operates to transfer data to and from the retention section and has a gate length shorter than the gate length of at least one of the drive transistor and the load transistor.

Hereinafter, with reference to the drawings, an example embodiment will be described. In the following examples, the characteristic configuration and operation of a semiconductor memory device will be mainly described, but other configurations and operations may exist in the semiconductor memory devices and these other configurations and operations are also be included in the scope of the disclosure.

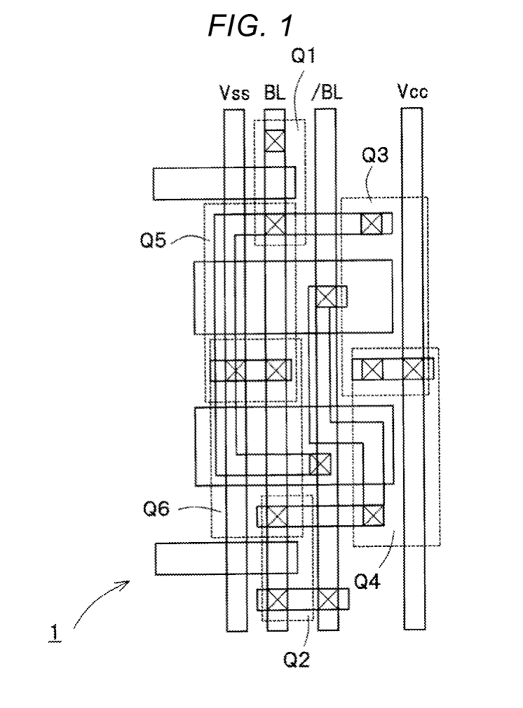

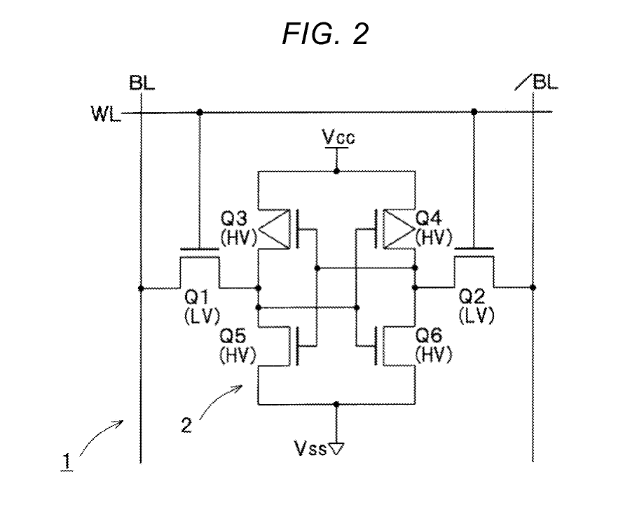

FIG. 1 is a layout diagram of principal portions of a semiconductor memory device 1 according to an embodiment. The semiconductor memory device 1 of FIG. 1 indicates the layout of an SRAM cell 1. FIG. 2 is a circuit diagram of one SRAM cell 1. First, based on FIG. 2, the circuit configuration of the SRAM cell 1 is described.

The SRAM cell 1 of FIG. 2 includes a retention section 2 and two transfer transistors (first and second transistors) Q1 and Q2. The retention section 2 retains data by using first conductivity-type load transistors (third and fourth transistors) Q3 and Q4 and second conductivity-type drive transistors (fifth and sixth transistors) Q5 and Q6. The transfer transistors Q1 and Q2 transfer data to and from the retention section 2. The transfer transistors Q1 and Q2 have a gate length shorter than the gate lengths of the load transistors Q3 and Q4 and the drive transistors Q5 and Q6.

The conductivity type of the load transistors Q3 and Q4 is different from the conductivity type of the transfer transistors Q1 and Q2 and the drive transistors Q5 and Q6. For example, the load transistors Q3 and Q4 are PMOS transistors and the transfer transistors Q1 and Q2 and the drive transistors Q5 and Q6 are NMOS transistors.

The load transistor Q3 and the drive transistor Q5 are connected in cascade between a power-supply voltage node (a first reference voltage node) Vcc and a ground node (a second reference voltage node) Vss, thus forming a first inverter. Likewise, the load transistor Q4 and the drive transistor Q6 are also connected in cascade between Vcc and Vss, thus forming a second inverter.

The transfer transistor Q1 performs the transfer of data to and from a connection node of the load transistor Q3 and the drive transistor Q5. Likewise, the transfer transistor Q2 performs the transfer of data to and from a connection node of the load transistor Q4 and the drive transistor Q6.

The transfer transistors Q1 and Q2, according to this embodiment, have a gate length shorter than the gate length of at least one of the load transistors Q3 and Q4 and the drive transistors Q5 and Q6. Hereinafter, an example in which the load transistors Q3 and Q4 and the drive transistors Q5 and Q6 are formed as high-voltage transistors (HV-MOSFETs) and the transfer transistors Q1 and Q2 are formed as low-voltage transistors (LV-MOSFETs) is described. The feature of the HV-MOSFET in this embodiment is that at least the gate length of the HV-MOSFET is longer than the gate length of the LV-MOSFET.

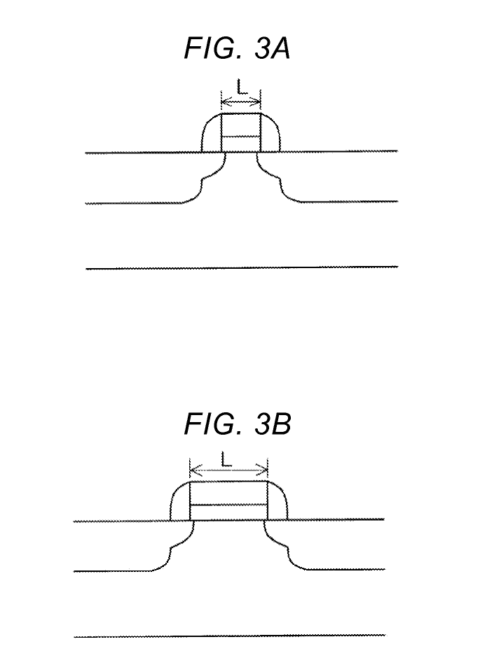

FIG. 3A is a schematic sectional view of the transfer transistors Q1 and Q2, and FIG. 3B is a schematic sectional view of the drive transistors Q5 and Q6. As is clear from a comparison of FIG. 3A and FIG. 3B, the gate length L of the transfer transistors Q1 and Q2 is shorter than the gate length L of the drive transistors Q5 and Q6. As a result, although the transfer transistors Q1 and Q2 maybe driven at faster speed than the drive transistors Q5 and Q6, the short gate length L of the transfer transistors Q1 and Q2 allows a leakage current to easily flow between the source and the drain thereof. However, in the SRAM cell 1, since the gate potential of the transfer transistors Q1 and Q2 is in a floating state (an inconstant state) while data is retained by the retention section 2, even when the gate length L is short, only a small leakage current flows between the source and the drain of each of the transfer transistors Q1 and Q2. Moreover, by forming the transfer transistors Q1 and Q2 as the LV-MOSFETs with a short gate length L, as compared to a case where all the six transistors in the SRAM cell 1 are formed as the HV-MOSFETs, it is possible to reduce the circuit area of the SRAM cell 1.

Next, the layout of the SRAM cell 1 according to this embodiment is described with reference to FIG. 1. As described above, in this embodiment, the transfer transistors Q1 and Q2 in the SRAM cell 1 are formed as the LV-MOSFETs, and the load transistors Q3 and Q4 and the drive transistors Q5 and Q6 are formed as the HV-MOSFETs. In the example of FIG. 1, the transfer transistors Q1 and Q2 are disposed at both vertical ends of a layout region, the drive transistors Q5 and Q6 are vertically disposed between the transfer transistors Q1 and Q2, and the load transistors Q3 and Q4 are vertically disposed in the lateral direction of these drive transistors. A layout pattern is formed of a plurality of layers. For example, in the lowermost layer (hereinafter, a first layer), a power-supply wiring section Vcc, a ground wiring section Vss, and bit lines BL and /BL are disposed, a first wiring layer is provided on a second layer on the first layer, and a second wiring layer is disposed on a third layer on the second layer. Moreover, though not depicted in FIG. 1, a third wiring layer for word line connection is disposed on a fourth layer on the third layer, for example. The layout diagram of FIG. 1 is an example and various modified examples are possible.

As is clear from the layout diagram of FIG. 1, the gate length L of the transfer transistors Q1 and Q2 is set so as to be shorter than the gate length L of the load transistors Q3 and Q4 and the drive transistors Q5 and Q6, whereby it is possible to shorten the vertical length of the SRAM cell 1.

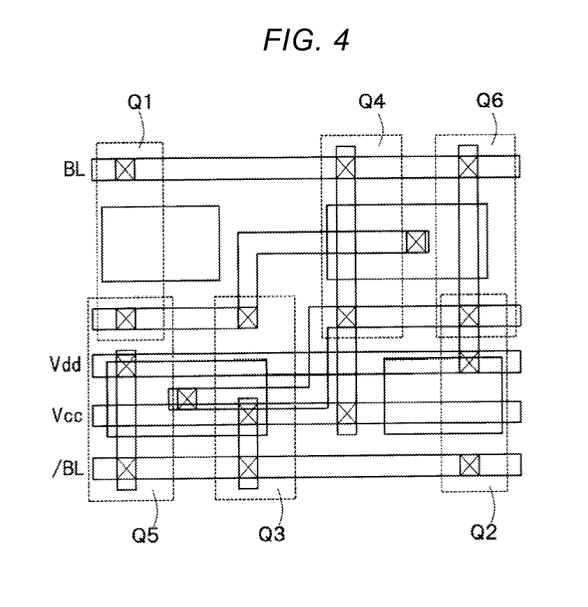

On the other hand, FIG. 4 is a layout diagram of an SRAM cell 1 according to a comparative example. In the SRAM cell 1 of FIG. 4, all the transistors in the SRAM cell 1 are formed as the HV-MOSFETs. In FIG. 4, the transfer transistors Q1 and Q2 are disposed in an upper left corner and a lower right corner, respectively, of a layout region, and one of the load transistors Q3 and Q4 and one of the drive transistors Q5 and Q6 and the other of the load transistors Q3 and Q4 and the other of the drive transistors Q5 and Q6 are disposed side by side in an upper right corner and a lower left corner. In FIGS. 1 and 4, the circuit area of each transistor is depicted by using a broken-line frame.

The circuit area of the load transistors Q3 and Q4 and the circuit area of the drive transistors Q5 and Q6 in FIG. 1 are about equal to the circuit area of the load transistors Q3 and Q4 and the circuit area of the drive transistors Q5 and Q6 in FIG. 4, but the circuit area of the transfer transistors Q1 and Q2 in FIG. 1 is smaller than the circuit area of the transfer transistors Q1 and Q2 in FIG. 4. As a result, in the SRAM cell 1 as a whole, FIG. 1 may reduce the circuit area by about 10% as compared to the circuit area of FIG. 4.

As described above, by making the gate length L of the transfer transistors Q1 and Q2 shorter than the gate length L of the drive transistors Q5 and Q6 and the load transistors Q3 and Q4, it is possible to reduce the circuit area of the SRAM cell 1 reliably. Moreover, since a leakage current does not flow through the transfer transistors Q1 and Q2 in principle while data is retained even when the transfer transistors Q1 and Q2 are formed as the LV-MOSFETs, the leakage characteristics are little affected.

In FIG. 1, an example in which only the transfer transistors Q1 and Q2 are formed as the LV-MOSFETs is described. However, the load transistors Q3 and Q4 may also be formed as the LV-MOSFETs leaving only the drive transistors Q5 and Q6 to be formed as the HV-MOSFETs.

Moreover, in the above description, an example in which only the gate length L of the transfer transistors Q1 and Q2 is made shorter than the gate length L of the load transistors Q3 and Q4 and the drive transistors Q5 and Q6 is described. However, not only the gate length L of the transfer transistors Q1 and Q2 according to this embodiment, but also the gate oxide film thereof, for example, may be made thinner than the gate oxide film of at least one of the drive transistors Q5 and Q6 and the load transistors Q3 and Q4.

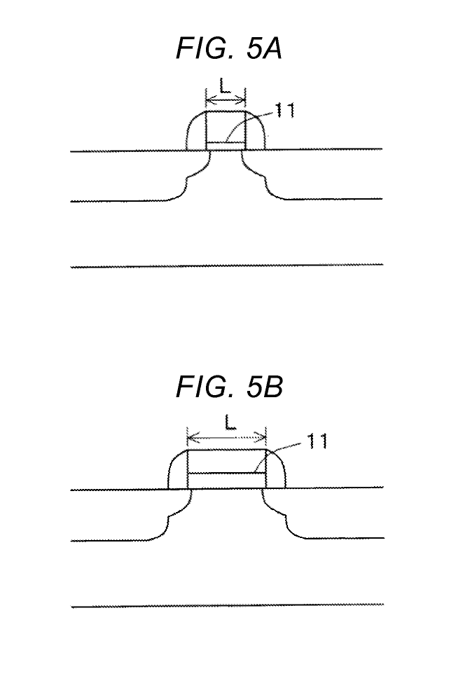

FIG. 5A is a schematic sectional view of the transfer transistors Q1 and Q2 according to a first modified example, and FIG. 5B is a schematic sectional view of the drive transistors Q5 and Q6. As depicted in FIG. 5A, in the first modified example, in addition to making the gate length L of the transfer transistors Q1 and Q2 shorter than the gate length L of the drive transistors Q5 and Q6, a gate oxide film 11 of each of the transfer transistors Q1 and Q2 is made thinner than a gate oxide film 11 of each of the drive transistors Q5 and Q6.

The thinner the gate oxide film 11 is made, the more likely leakage occurs. However, as described above, since the gates of the transfer transistors Q1 and Q2 are in a floating state while data is retained by the retention section 2, the leakage does not become a problem. Therefore, even when the gate oxide film 11 of each of the transfer transistors Q1 and Q2 is made thinner, there is no possibility of impairment of the leakage characteristics.

Furthermore, not only the gate length L of the transfer transistors Q1 and Q2 according to this embodiment, but also the junction depth of a diffusion layer of each of the transfer transistors Q1 and Q2, for example, may be made less than the junction depth of at least one of the drive transistors Q5 and Q6 and the load transistors Q3 and Q4.

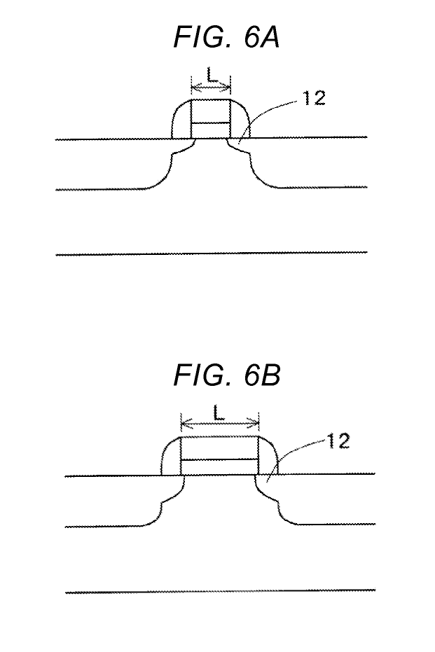

FIG. 6A is a schematic sectional view of the transfer transistors Q1 and Q2 according to a second modified example, and FIG. 6B is a schematic sectional view of the drive transistors Q5 and Q6. As depicted in FIG. 6A, in the second modified example, a junction depth 12 of a diffusion layer of each of the transfer transistors Q1 and Q2 is made less than a junction depth 12 of the drive transistors Q5 and Q6.

As the junction depth 12 of the diffusion layer is reduced, leakage is more likely to occur. However, as described above, since the gates of the transfer transistors Q1 and Q2 are in a floating state while data is retained by the retention section 2, the leakage does not become a problem. Therefore, even when the junction depth 12 of the diffusion layer of each of the transfer transistors Q1 and Q2 is reduced, there is no possibility of impairment of the leakage characteristics.

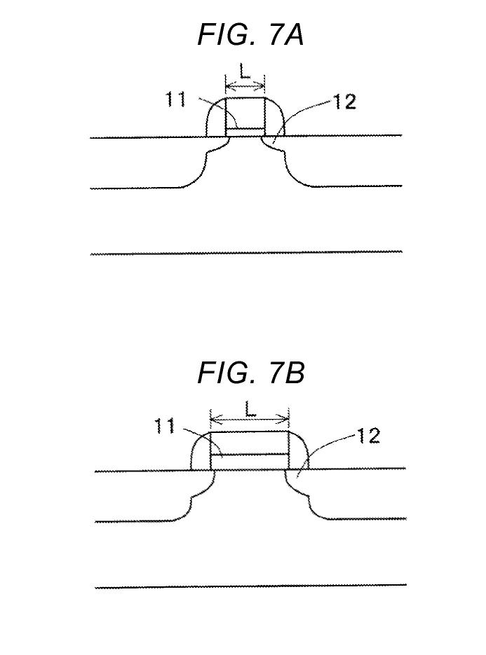

It is possible to combine the first modified example and the second modified example described above. FIG. 7A is a schematic sectional view of the transfer transistors Q1 and Q2 according to a third modified example, and FIG. 7B is a schematic sectional view of the drive transistors Q5 and Q6. As depicted in FIG. 7A, in the third modified example, the gate length L of the transfer transistors Q1 and Q2 is made shorter than the gate length L of the drive transistors Q5 and Q6, the gate oxide film 11 of each of the transfer transistors Q1 and Q2 is made thinner than the gate oxide film 11 of each of the drive transistors Q5 and Q6, and the junction depth 12 of the diffusion layer of each of the transfer transistors Q1 and Q2 is made less than the junction depth 12 of the diffusion layer of each of the drive transistors Q5 and Q6.

When the transfer transistors Q1 and Q2 are formed as the LV-MOSFETs and the drive transistors Q5 and Q6 and the load transistors Q3 and Q4 are formed as the HV-MOSFETs, not only does the gate length L of the LV-MOSFET become shorter but the gate oxide film 11 and the junction depth 12 of the diffusion layer thereof also become thinner and less than the gate oxide film 11 and the junction depth 12 of the diffusion layer of the HV-MOSFET, and the same structure as the structure of FIG. 7A is obtained. Also in this case, it is possible to reduce the circuit area without impairment of the leakage characteristics.

As described above, in this embodiment, since the gate length L of the transfer transistors Q1 and Q2 in the SRAM cell 1 is made shorter than the gate length L of the drive transistors Q5 and Q6 and the load transistors Q3 and Q4, it is possible to reduce the circuit area of the SRAM cell 1 accordingly. Moreover, even when the gate length L of the transfer transistors Q1 and Q2 is made shorter, since the leakage characteristics are not affected much, it is possible to achieve a reduction in the circuit area of the SRAM cell 1 without impairment of the leakage characteristics.

While certain embodiments have been described, these embodiments have been presented by way of example only, and are not intended to limit the scope of the inventions . Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a retention section including first conductivity-type transistors in a load transistor section and second conductivity-type transistors in a drive transistor section; and
a transfer transistor section including a transfer transistor that is operated to transfer data to and from the retention section and has a gate length shorter than a gate length of at least one of the transistors in the retention section.

2. The semiconductor memory device according to claim 1, wherein
the transfer transistor has a gate oxide film that is thinner than a gate oxide film of at least one of transistors in the retention section.

3. The semiconductor memory device according to claim 1, wherein
a junction depth of a diffusion layer of the transfer transistor is less than a junction depth of a diffusion layer of at least one of the transistors in the retention section.

4. The semiconductor memory device according to claim 1, wherein
the transfer transistor section includes a first transfer transistor and a second transfer transistor,
the load transistor section includes third and fourth transistors,
the drive transistor section includes fifth and sixth transistors,
the third and fifth transistors are connected between first and second reference voltage nodes,
the fourth and sixth transistors are connected between the first and second reference voltage nodes,
the first transfer transistor transfers data to and from a connection node that is between the third and fifth transistors,
the second transfer transistor transfers data to and from a connection node that is between the fourth and sixth transistors, and
the first and second transfer transistors have a gate length that is shorter than each gate length of the third to sixth transistors.

5. The semiconductor memory device according to claim 4, wherein
the first and second transfer transistors have a gate oxide film that is thinner than each gate oxide film of the third to sixth transistors.

6. The semiconductor memory device according to claim 4, wherein
the first and second transfer transistors have a diffusion layer junction depth that is less than each diffusion layer junction depth of the third to sixth transistors.

7. The semiconductor memory device according to claim 1, wherein the retention section and the transfer transistor section are included in a static random access memory (SRAM) cell.

8. A static memory cell, comprising:
a retention section including a drive section and a load section that is coupled to the drive section,
the drive section including first and second drive transistors, each having a source connected to a first reference voltage terminal, the first drive transistor having a gate connected to a drain of the second drive transistor, the second drive transistor having a gate connected to a drain of the first drive transistor,
the load section including first and second load transistors, each having a source connected to a second reference voltage terminal, the first load transistor having a drain connected to the drain of the first drive transistor, and a gate of the first load transistor connected to the gate of the first drive transistor, the second load transistor having a drain connected to the drain of the second drive transistor, and a gate of the second load transistor connected to the gate of the second drive transistor; and
a transfer section including first and second transfer transistors, each having a gate connected to a word line, the first transfer transistor connected between a first bit line and the drain of the first drive transistor, and the second transfer transistor connected between a second bit line and the drain of the second drive transistor,
wherein the first and second transfer transistors have a gate length that is less than a gate length of at least one of the transistors in the retention section.

9. The static memory cell according to claim 8, wherein the first and second transfer transistors have a gate oxide film that is thinner than a gate oxide film of at least one of the transistors in the retention section.

10. The static memory cell according to claim 8, wherein the first and second transfer transistors have a diffusion layer junction depth that is less than a diffusion layer junction depth of at least one of the transistors in the retention section.

11. The static memory cell according to claim 8, wherein the transistors of the retention section are high-voltage transistors (HV-MOSFETS) and the first and second transfer transistors are low voltage transistors (LV-MOSFETS).

12. The static memory cell according to claim 11, wherein the first and second transfer transistors have a gate length less than a gate length of each of the first and second drive transistors.

13. The static memory cell according to claim 8, wherein the first and second drive transistors are high-voltage transistors (HV-MOSFETS), the first and second transfer transistors are low voltage transistors (LV-MOSFETS), and the first and second load transistor are LV-MOSFETS.

14. The static memory cell according to claim 8, wherein the first and second drive transistors are NMOS transistors and the first and second load transistors are PMOS transistors.

15. A static memory cell, comprising:
a first inverter having an output terminal, an input terminal, and a first pair of transistors;
a second inverter having an output terminal, input terminal, and a second pair of transistors, wherein the first inverter output terminal is connected to the second inverter input terminal and the second inverter output terminal is connected to the first inverter input terminal; and
first and second transfer transistors, each having a gate connected to a word line, the first transfer transistor connected between a first bit line and the input terminal of the second inverter, and the second transfer transistor connected between a second bit line and the input terminal of the first inverter,
wherein the first and second transfer transistors have a gate length that is shorter than a gate length of at least one of the transistors in the first and second inverters.

16. The static memory cell according to claim 15, wherein the first and second transfer transistors have a gate oxide film that is thinner than a gate oxide film of at least one of the transistors in the first and second inverters.

17. The static memory cell according to claim 15, wherein the first and second transfer transistors have a diffusion layer junction depth that is less than a diffusion layer junction depth of at least one of the transistors in the first and second inverters.

18. The static memory cell according to claim 15, wherein the transistors of the first and second inverters are high voltage transistors (HV-MOSFETS) and the first and second transfer transistors are low voltage transistors (LV-MOSFETS).

19. The static memory cell according to claim 15, wherein the first and second transfer transistors are low voltage transistors (LV-MOSFETS).

20. The static memory cell according to claim 15, wherein each inverter includes an NMOS transistor and a PMOS transistor.
